(19) United States
(12) Patent Application Publication
(10) Pub. No.: US 2009/0206394 A1
(43) Pub. Date: Aug. 20, 2009

(54) Strained Channel PMOS Transistor and Corresponding Production Method

(76) Inventor: Daniel Chanemougame, Grenoble (FR)

Correspondence Address: DOCKET CLERK, P.O. DRAWER 800889, DALLAS, TX, 75380, US

(21) Appl. No.: 11/886,793

(22) PCT Filed: Apr. 1, 2005
(86) PCT No.: PCT/FR2005/000792

§ 371 Date: Jan. 27, 2009

(51) Int. Cl. H01L 29/78; H01L 21/20

(52) U.S. Cl. 257/327; 438/478; 257/E29.255; 257/E21.09

(57) ABSTRACT

The PMOS transistor (TR) has a channel width W of less than 1 micrometer, a channel length of less than or equal to 0.1 micrometer, and a distance of more than 0.5 micrometer between one edge of the channel and the corresponding edge of the active zone. The production of the active zone includes epitaxy on a first semiconductor material (SB) of an intermediate layer (CI) formed by a second semiconductor material having a lattice parameter greater than that of the first material, and epitaxy on the intermediate layer (CI) of an upper layer (CS) formed by the first material, anisotropic etching (GR) of the upper layer and the intermediate layer on either side of the two sidewalls of the gate region, and filling of the recesses thus formed by epitaxy (EPX) of the first material.

The invention relates to integrated circuits and, more particularly, to p-type channel insulated gate field effect transistors (PMOS transistors).

It is known, in particular from the article by BIANCHI et al. entitled “Accurate Modeling of Trench Isolation Induced Mechanical Stress Effects on MOSFET Electrical Performance”, IEEE 2002, that the electrical insulation zone surrounding the active zone of the transistor is a significant cause of mechanical stress variations in the conduction channel of an MOS transistor. When the conduction channel has a small width W, for example less than 1 μm, and the distance a measured perpendicularly to the width of the channel between the gate edge and the corresponding edge of the active zone is large, for example more than 0.5 μm (which is customary in conventional MOS transistor architectures so as to allow easy contact making on the source and drain regions), a uniaxial compression of the conduction channel is produced in the direction of its width. This results in a degradation of the electrical performance of the transistor.

It has nevertheless been shown in the article by CHAN et al. entitled “High Speed 45 nm Gate Length CMOSFETs Integrated into a 90 nm Bulk Technology Incorporating Strain Engineering”, IEEE 2003, that reduction of the distance a combined with a small value of W then causes biaxial compression of the conduction channel, which makes it possible to improve the electrical performance of PMOS transistors.

This biaxial compression effect, however, is obtained at the cost of modifying the geometrical shape of the transistor i.e. by using values of the order of 0.1 to 0.2μ for a. Moreover, reducing the distance a not only leads to a nonstandard architecture of a PMOS transistor, but also to difficulties for easy contact making on the source and drain zones of such a transistor.

The invention aims to provide a solution to this problem.

It is an object of the invention to provide a PMOS transistor architecture which has a small channel width and a sufficiently large distance between the gate edge and the active zone edge in order to preserve a conventional architecture of the PMOS transistor, and in particular allow easy contact making on the source and drain zones, while improving the electrical performance of such a PMOS transistor.

The invention therefore relates in particular to a PMOS transistor architecture having a small channel width W, i.e. typically less than 1 μm, and a distance between one edge of the channel and the corresponding edge of the active zone of more than 0.5μ, and having a conduction channel compressed biaxially i.e. in the direction of the width of the channel and in the direction of the length of this channel.

The mobility of the holes is thus improved owing to this biaxial compression, and the electrical-performance of the PMOS transistor is consequently improved, while maintaining the possibility of easy contact making. on the source and drain regions.

One aspect of the invention relates to a method for fabricating a PMOS transistor in and on an active zone of an integrated circuit. This PMOS transistor has a channel width W of less than 1 μm (10⁻⁶ m), a channel length of less than or equal to 0.1 μm and a distance of more than 0.5 μm between one edge of the channel and the corresponding edge of the active zone.

The production of the active zone includes epitaxy on a first semiconductor material, for example silicon, of an intermediate layer formed by a second semiconductor material having a lattice parameter greater than that of the first material. This second material may, for example, comprise an alloy of silicon and germanium.

The production of the active zone also includes epitaxy on the intermediate layer of an upper layer formed by the first material, for example silicon, and anisotropic etching of the upper layer and the intermediate layer on either side of the two sidewalls of the gate region, and filling of the recesses thus formed by epitaxy of the first material, for example silicon.

According to this aspect of the invention, the compression along the width of the channel is thus provided by the electrical insulation zone surrounding the active zone, for a value W of less than 1 μm, while the compression in the perpendicular direction, i.e. in the conduction direction, results here from the filling of the recesses by epitaxy. This is because owing to the lattice parameter mismatch between the first material, for example silicon, and the second material of the intermediate layer, for example silicon-germanium, which is in biaxial compression in the plane of the channel, the second material is compressed perpendicularly to this plane by the epitaxy of the first material used to fill the recesses on either side of the gate region. After re-obtaining mechanical equilibrium, the channel composed of silicon returns to compression in the direction of the conduction, i.e. in the direction of its length.

The invention finds its full advantages for a length L of the channel less than 100 nm and, for reasons of compression efficiency in the conduction direction, it is particularly advantageous to select a particularly small channel, for example having a length of less than or equal to 50 nm.

The invention also relates to an integrated circuit comprising at least one PMOS transistor obtained by such a method.

Another aspect of the invention likewise relates to an integrated circuit comprising at least one PMOS transistor having an active zone formed by a first semiconductor material, for example silicon, and surrounded by an electrically insulating material, and a gate semiconductor region extending below a part of the active zone in a first direction. The width W of the channel of the transistor measured in the first direction is less than 1 μm and the length L of the channel measured in a second direction orthogonal to the first is less than or equal to 100 nm. The distance a measured in said second direction between one edge of the channel and the corresponding edge of the active zone is more than 0.5 μm. The PMOS transistor also comprises, embedded within the active zone, a layer extending in said first direction parallel to the gate, below and at a distance from it, this layer being formed by a second semiconductor material, for example an alloy of silicon and germanium, having a lattice parameter greater than that of the first semiconductor material.

Other advantages and characteristics of the invention will become apparent on studying the detailed description of embodiments and implementations, which do not imply any limitation, and the appended drawings in which:

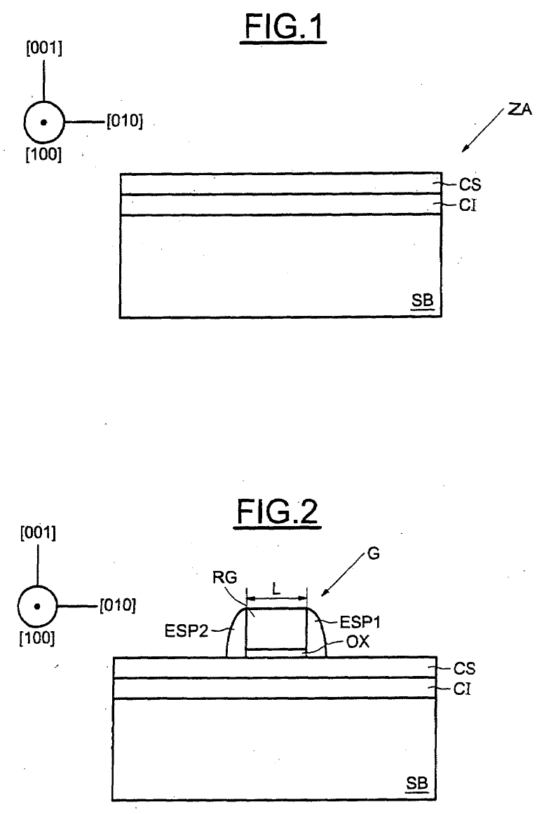

FIGS. 1 to 4 schematically illustrate the main steps of an implementation of a method according to the invention leading to an embodiment of a PMOS transistor according to the invention, and

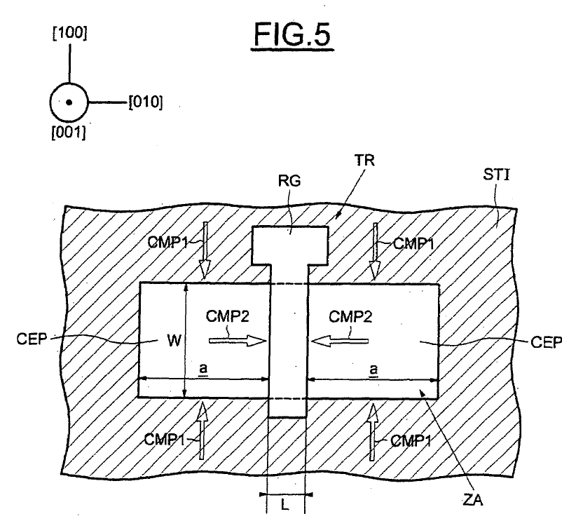

FIG. 5 is a schematic plan view of an embodiment of a PMOS transistor according to the invention.

In FIG. 1, the reference ZA denotes a semiconductor active zone surrounded by an electrical insulation zone STI (FIG. 5), for example of the “shallow trench” type.

The active zone ZA comprises a substrate SB, for example of silicon.

An intermediate layer CI is then formed on the substrate SB by epitaxy. This intermediate layer is formed by a material having a lattice parameter in equilibrium greater than that of silicon. This material thus comprises, for example, an alloy of silicon and germanium.

Epitaxy is a conventional operation well known to the person skilled in the art.

This being the case, although germanium and silicon are well miscible in all proportions, the corresponding silicon/germanium alloy is never lattice matched with silicon. Thus, the lattice parameter increases by 4.2% between pure silicon (5.43 Å) and pure germanium (5.65 Å) according to a substantially linear law. During the growth, the material of the epitaxial layer CI tends to adapt its lattice parameter in the growth plane to that of the substrate, and to expand in the perpendicular direction. Hence, in the present case, the silicon-germanium alloy forming the intermediate layer CI is in biaxial compression in the (001) plane defined by the two directions [010] and [100] and perpendicular to the [001] direction. For this reason, because of the constant-volume elastic deformation of silicon-germanium, it has a vertical lattice larger than that of silicon.

An upper silicon layer CS is subsequently formed on the intermediate layer CI by epitaxy.

By way of indication, the thickness of the layer CI is for example 30 nm while the thickness of the silicon layer CS is of the order of 20 nm.

A semiconductor gate region RG insulated from the upper layer CS by a gate oxide OX is subsequently produced conventionally and in a manner known per se (FIG. 2).

As illustrated in FIG. 5, this gate semiconductor region extends essentially in a first direction, here the [100] direction, and overlaps the active zone ZA. The value of the overlap W here defines the width of the conduction channel of the transistor TR.

Furthermore, the width L of the gate region in its part overlapping the active zone in fact defines the length L of the conduction channel, the length being measured in the [010] direction.

Before carrying out the conventional formation of spacers ESP1 and ESP2 on the two sidewalls of the gate region RG, first implantation of dopants is generally carried out in the active zone on either side of the sidewalls of the gate RG. The dopant implantation carried out before forming the spacers makes it possible to create extensions of the source and drain regions.

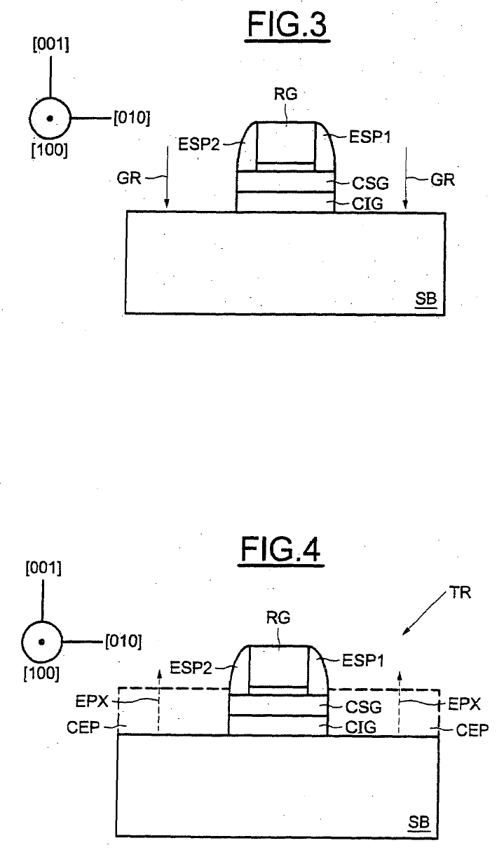

Then, after having produced the spacers ESP1 and ESP2 of the gate G conventionally and in a manner known per se, anisotropic etching GR of the silicon layer CS and the silicon-germanium layer CI is carried out on either side of the spacers ESP1 and ESP2 (FIG. 3).

The anisotropic etching GR, for example plasma etching, is conventional and known per se.

The structure illustrated in FIG. 3 is obtained at the end of this etching step, in which the unetched intermediate layer CIG is formed by silicon-germanium in biaxial compression in the (001) plane of the channel. This layer CIG is surmounted by the unetched part CSG of the upper layer, which incorporates the conduction channel of the transistor.

Next, as illustrated in FIG. 4, silicon epitaxy is carried out in the recesses formed in the active zone ZA, which lie on either side of the layers CIG and CSG and result from the anisotropic etching GR. The silicon epitaxy EPX will lead to the formation of epitaxial regions CEP in which the source and drain regions of the transistor will be formed by subsequent implantation.

During this epitaxy operation EPX, the silicon which grows on the sidewalls of the layer CIG intrinsically has a vertical lattice smaller than the vertical lattice of the silicon-germanium of the layer CIG which is in biaxial compression. The bulkier material, i.e. silicon, will therefore impose its lattice on the silicon-germanium. This will then return to vertical compression in the [001] direction. The layer CSG, and consequently the conduction channel, are compressed on either side after re-obtaining mechanical equilibrium, specifically in the [010] direction.

Of course, the greater the length L of the gate is, i.e. the longer the channel is, the less efficient is the compression effect resulting from the epitaxy, the edges of the silicon-germanium being commensurately further from the center of the channel.

This is the reason why PMOS transistors will generally be selected having a channel length L of less than 100 nm, and in particular advantageously less than or equal to 50 nm.

Thus, as illustrated in FIG. 5, the conduction channel of the PMOS transistor TR is stressed biaxially in the (001) plane, i.e. in the [010] and [100] directions. This is illustrated by the compression arrows CMP1 and CMP2 in FIG. 5.

The transistor of FIG. 5 has a channel width W of less than 1 μm, for example less than or equal to 0.3μ.

The distance a between the edge of the gate region and the corresponding edge of the active zone is more than 0.5 μm, for example more than 0.8 μm, which corresponds to a conventional dimension for a PMOS transistor allowing easy contact making on the source and drain regions.

Although the active zone ZA in FIG. 5 is a rectangular zone with the gate region centered on this active zone, the invention also applies to PMOS transistors in which the shape of the active zone ZA is irregular, i.e. it may for example have an asymmetry in the distances a between each of the edges of the gate region and the corresponding edge of the active zone (resulting from a gate RG not centered on the active zone). The active zone may also have portions of different lengths (different values of a) in the [010] direction, so long as at least one of these portions has a length a of more than 0.5 μm in order to allow contact making.

1-8. (canceled)

9. A method of fabricating a PMOS transistor in and on an active zone of an integrated circuit, the method comprising:
disposing epitaxy on an intermediate layer on a first semiconductor material, wherein the intermediate layer is formed by a second semiconductor material having a lattice parameter greater than that of the first semiconductor material;
disposing epitaxy on an upper layer of the intermediate layer, wherein the second intermediate layer is formed by the first semiconductor material;
etching the upper layer, the first intermediate layer and the second intermediate layer on either side of two sidewalls of a gate region; and
filling recesses formed by the epitaxy of the first material with silicon.

10. The method according to claim 9, wherein the etching comprises anisotropic etching.

11. The method according to claim 9, wherein the PMOS transistor has a channel width of less than 1 micrometer, a channel length of less than or equal to 0.1 micrometer, and a distance a of more than 0.5 micrometer between one edge of the channel and the corresponding edge of the active zone.

12. The method according to claim 11, wherein the length of the channel is less than or equal to 50 nanometers.

13. The method according to claim 11, wherein the width of the channel is less than or equal to 0.3 micrometer and a is more than 0.8 micrometer.

14. The method according to claim 9, wherein the first semiconductor material is silicon and the second semiconductor material comprise an alloy of silicon and germanium.

15. The method according to claim 9, wherein the first semiconductor material comprises silicon.

16. The method according to claim 9, wherein the second semiconductor material comprises silicon-germanium.

17. For use in an integrated circuit, a PMOS transistor comprising:
an active zone formed by a first semiconductor material and surrounded by an electrically insulating material, and a gate semiconductor region extending above a part of the active zone in a first direction,
wherein a width of the channel of the transistor measured in a first direction is less than 1 micrometer and the length of the channel measured in a second direction orthogonal to the first is less than or equal to 100 nanometers, and
wherein the distance measured in the second direction between one edge of the channel and the corresponding edge of the active zone is more than 0.5 micrometer; and
a layer which extends in said first direction parallel to the gate, below and at a distance from it, and is formed by a second semiconductor material having a lattice parameter greater than that of the first semiconductor material, wherein the layer is embedded within the active zone.

18. The transistor according to claim 17, wherein the first material is silicon and the second material comprises an alloy of silicon and germanium.

19. The transistor according to claim 17, wherein the length of the channel is less than or equal to 50 nanometers.

20. The transistor according to claim 17, wherein the width of the channel is less than or equal to 0.3 micrometer and a is more than 0.8 micrometer.

21. The transistor according to claim 17, wherein the first semiconductor material comprises silicon.

22. The transistor according to claim 17, wherein the second semiconductor material comprises silicon-germanium.

23. A stressed channel PMOS transistor comprising:
an active zone formed by a first semiconductor material and surrounded by an electrically insulating material, and a gate semiconductor region extending above a part of the active zone in a first direction,
wherein a width of the channel of the transistor measured in a first direction is less than 1 micrometer and the length of the channel measured in a second direction orthogonal to the first is less than or equal to 100 nanometers, and
wherein the distance measured in the second direction between one edge of the channel and the corresponding edge of the active zone is more than 0.5 micrometer; and
a layer which extends in said first direction parallel to the gate, below and at a distance from it, and is formed by a second semiconductor material having a lattice parameter greater than that of the first semiconductor material, wherein the layer is embedded within the active zone.

24. The transistor according to claim 23, wherein the first material is silicon and the second material comprises an alloy of silicon and germanium.

25. The transistor according to claim 23, wherein the length of the channel is less than or equal to 50 nanometers.

26. The transistor according to claim 23, wherein the width of the channel is less than or equal to 0.3 micrometer and a is more than 0.8 micrometer.

27. The transistor according to claim 23, wherein the first semiconductor material comprises silicon.

28. The transistor according to claim 23, wherein the second semiconductor material comprises silicon-germanium.
